(19) United States
(12) Patent Application Publication
(10) Pub. No.: US 2026/0223618 A1
(43) Pub. Date: Jul. 30, 2026

(54) METHOD FOR CLEANING A SEMICONDUCTOR WAFER

(71) Applicant: Siltronic AG, Munich (DE)

(72) Inventors: Albert KÜHNSTETTER, Burghausen (DE); Damian BROCK, Sankt Wolfgang (DE)

(21) Appl. No.: 19/152,040

(22) PCT Filed: Jan. 23, 2024
(86) PCT No.: PCT/EP2024/051513

§ 371 Date: Jul. 30, 2025

(30) Foreign Application Priority Data
Feb. 2, 2023 (EP) 23154649.0

(51) Int. Cl. H10P 70/00

(52) U.S. Cl. CPC H10P 70/18

(57) ABSTRACT

A facing and reverse side of a semiconductor wafer are cleaned by: cleaning the facing side by, in order: precleaning with water such that the facing side is still wet as the next cleaning step begins; a first cleaning step with ozonized water and a subsequent rinsing step with purified water; a second cleaning step with a treatment with ozonized water followed by a treatment with a liquid containing HF; and a third cleaning step with ozonized water and a subsequent rinsing with purified water. Next, the facing side and the reverse side are jointly cleaned by: a fourth cleaning step, which includes a treatment with ozonized water followed by a treatment with a liquid comprising HF, and a drying step, in which both the facing side and the reverse side of the semiconductor wafer are dried.

### CROSS REFERENCE TO RELATED APPLICATIONS

This application is a U.S. National Phase application under 35 U.S.C. § 371 of International Application No. PCT/EP2024/051513, filed on Jan. 23, 2024, and claims benefit to European Patent Application No. EP 23154649.0, filed on Feb. 2, 2023. The International Application was published in German on Aug. 8, 2024 as WO 2024/160595 A1 under PCT Article 21(2).

### FIELD

The present disclosure is directed to cleaning a semiconductor wafer.

### BACKGROUND

Semiconductor wafers used, for example, as substrates for fabrication of microelectronic components, usually silicon wafers, are cleaned by wet-chemical methods after having been polished, coated (by epitaxial deposition, for example) or subjected to steps of thermal treatment (annealing) and/or in advance of high-temperature process steps.

The aim of the cleaning is as far as possible to remove any contamination of the semiconductor wafers, with metals such as copper or with organic substances, and also with particles adhering to the wafer surface, for example, since in the course of the subsequent fabrication of components, such contamination leads to problems of, for example, uneven growth of the gate oxides or uneven deposition of the polysilicon gates.

The cleaning methods employed include single-wafer methods, in which a semiconductor wafer is set into rapid rotation about its center axis while being first cleaned with one or more liquids and then rinsed with deionized water and dried. The liquids are applied to the rotating semiconductor wafer and accelerated toward the wafer edge by the centrifugal force, causing the liquids to run off at the outside and form a generally blanket thin film on the wafer surface. On subsequent drying with further rotation of the semiconductor wafer, with addition of a vapor which reduces the surface tension of the liquid film (e.g., isopropanol vapor), for example, the liquid film runs off completely to the outside. Methods of this kind are described in, for example, US 2004/0 103 915 A1 and EP 0 905 747 A1.

US 2014/048 100 A1 discloses a method for cleaning semiconductor wafers wherein the following method steps are used:
(1) a first cleaning step for cleaning with ozonized water and subsequent rinsing step with purified water,
(2) a second cleaning step, including a treatment step with ozonized water followed by a treatment step with a liquid containing HF, where the second cleaning step can be repeated multiply,
(3) a third cleaning step for cleaning with ozonized water and subsequent rinsing step with purified water,
(4) a drying step in which the side of the semiconductor wafer is dried.

When testing out this method, the inventors discovered that defect patterns can occur on the wafer which are measurable with a localized light scatterers (LLS) measurement. These defects apparently occur preferentially in the center of the substrate and may negatively impact the behavior of the affected semiconductor wafers in the process of component fabrication. If, when using this process, both one side and the other side of the semiconductor wafer are treated, additional defects occur in the edge region of the semiconductor wafer on the respective opposite side. For example, if the reverse side of a semiconductor wafer is cleaned with this method, particles can occur thereafter in the edge region of the facing side, and may be disruptive to the semiconductor component process.

### SUMMARY

In an embodiment, the present disclosure provides a method for cleaning a facing side and a reverse side of a semiconductor wafer. The method includes, in the order given: cleaning the facing side of the semiconductor wafer, the cleaning of the facing side including, in the order given: a precleaning step with water, the precleaning step executed such that the facing side is still wet as the next cleaning step begins; a first cleaning step including cleaning with ozonized water and a subsequent rinsing step with purified water; a second cleaning step, which includes a treatment step with ozonized water followed by a treatment step with a liquid containing hydrogen fluoride (HF); and a third cleaning step including cleaning with ozonized water and a subsequent rinsing step with purified water; and jointly cleaning the facing side and the reverse side of the semiconductor wafer, the jointly cleaning the facing side and the reverse side including: a fourth cleaning step, which includes a treatment step with ozonized water followed by a treatment step with a liquid comprising HF, and a drying step, in which both the facing side and the reverse side of the semiconductor wafer are dried.

### BRIEF DESCRIPTION OF THE DRAWINGS

Subject matter of the present disclosure will be described in even greater detail below based on the exemplary FIGURE. All features described and/or illustrated herein can be used alone or combined in different combinations. The features and advantages of various embodiments will become apparent by reading the following detailed description with reference to the attached drawing, which illustrates the following:

FIG. 1 shows the number of defects D in relative units as a function of the radius R of a semiconductor wafer with a nominal diameter of 300 mm.

### DETAILED DESCRIPTION

Aspects of the present disclosure provide a method for cleaning a semiconductor wafer that does not cause these defects or at least minimizes the likelihood of these defects occurring.

Below is an explanation of select abbreviations used in this description:
DIW deionized water.
O3W ozonized water consisting of 15-20 ppm ozone (O₃) in solution in deionized water.

SC1 “Standard Clean 1” containing 0.3% tetramethylammonium hydroxide (TMAH, [N(CH₃)₄]OH) and 0.7% hydrogen peroxide (H₂O₂) in deionized water.

HF 0.5%-1% hydrogen fluoride (HF) in solution in deionized water.

DRY drying process carried out in 100% nitrogen atmosphere (N₂).

D number of defects.

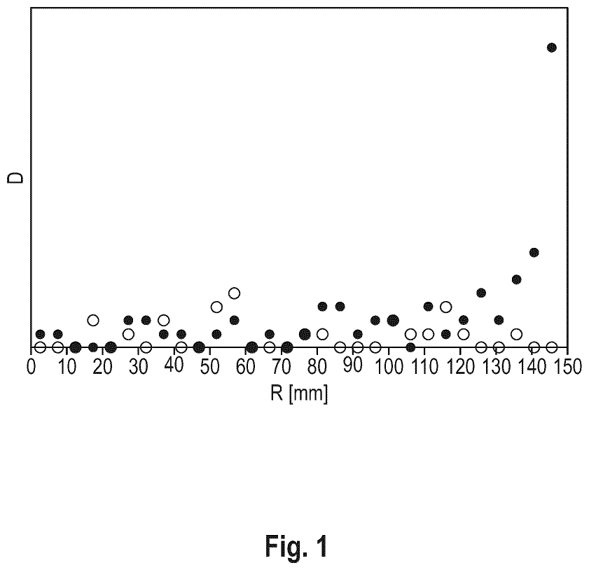

FIG. 1 shows, as an illustration, the number of defects D in relative units as a function of the radius R of the semiconductor wafer with a nominal diameter of 300 mm. The solid circles represent the number of defects obtained on cleaning according to the prior art. The hollow circles, conversely, represent the defects obtained on cleaning according to the inventive method. It is clearly apparent that the inventive method is better able to avoid defects at the edge of the semiconductor wafer than the prior art method.

On testing out a state of the art method for cleaning semiconductor wafers using an apparatus for cleaning single wafers (single-wafer cleaner), the inventors determined that defect patterns can occur on the wafer which are measurable with an LLS measurement.

These defect patterns can be visualized by a scattered light measurement, with an instrument from KLA-Tencor using the Surfscan SP 1 MX, for example, and are therefore also referred to as the localized light scattering burden. WO 2005 101 483 A1 discloses a method for scattered light measurement of epitaxially coated semiconductor wafers.

As shown by FIG. 1, these defects occur preferentially at the edge of the semiconductor wafer. They may negatively impact the behavior of the affected semiconductor wafers in the component fabrication process.

If the reverse side of a semiconductor wafer is cleaned using the state of the art method, the semiconductor wafer has an increased defect density in the edge region of the facing side. The inventors have been able to demonstrate these defects using the stated measurement technique.

After cleaning, defects are not tolerable on either the facing side or the reverse side of the semiconductor wafer, and must therefore be minimized.

In attempting to eliminate these defects, the inventors found that it is necessary first to clean the facing side of the semiconductor wafer and, subsequently, to clean both sides jointly.

In accordance with an aspect of the present disclosure, the facing side of the semiconductor wafer is first subjected to a precleaning step in which the liquid consists substantially of water. The inventors have determined that the facing side should still be wet before the subsequent first cleaning step for cleaning with ozonized water, with subsequent rinsing step with purified water, begins.

In accordance with an aspect of the present disclosure, a second cleaning step is carried out thereafter, and contains a treatment step with ozonized water, followed by a treatment step with a liquid containing hydrogen fluoride (HF).

After the second cleaning step, in accordance with an aspect of the present disclosure, a third cleaning step for cleaning with ozonized water and subsequent rinsing step with purified water is carried out.

Thereafter, in accordance with an aspect of the present disclosure, joint cleaning of the facing side and the reverse side of the semiconductor wafer is carried out, containing a fourth cleaning step, which contains a treatment step with ozonized water, followed by a treatment step with a liquid containing HF, and a drying step in which both sides of the semiconductor wafer are dried.

Preferably, during the precleaning step, the fraction of ozonized water is increased from 0% at the start of the precleaning step to 100% at the end of the precleaning step, with the duration with a fraction of less than 5% being less than 10 s and greater than 1 s. This continuous increase in the fraction of ozonized water between the precleaning step and on to the first cleaning step apparently has the effect of lowering even further the number of defects found.

More preferably, the precleaning step lasts for at least 1 s and not more than 15 s.

More preferably, the facing side of the semiconductor wafer is aligned horizontally and during the precleaning step rotates at a rate of greater than 500 rpm and less than 1000 rpm.

More preferably, in the precleaning step, the water is applied using a nozzle and the nozzle flow here is between 0.5 m/s and 2 m/s, the associated flow rate being between 0.5 L/min and 1.5 L/min.

More preferably, the nozzle used is aligned such that the direction of the nozzle flow forms an angle α with the surface of the semiconductor wafer that is smaller than 70° and larger than 30°.

More preferably, the precleaning step lasts for at least 1 s and not more than 15 s; very preferably, the step lasts for at least 3 s and not more than 8 s.

For the method it is preferred if the side of the semiconductor wafer that is to be cleaned is aligned horizontally and during the precleaning step rotates at a rate of greater than 500 rpm and less than 1000 rpm.

It is more preferred if, in the precleaning step, the water is applied using a nozzle. The nozzle flow here is more preferably between 0.5 m/s and 2 m/s, the associated flow rate being preferably between 0.5 L/min and 1.5 L/min.

it is likewise preferred if the nozzle is aligned such that the direction of the nozzle flow forms an angle α with the surface of the semiconductor wafer that is smaller than 70° and larger than 30°.

One particularly preferred embodiment of a method for cleaning the facing side according to the present disclosure is shown in Table 1.

TABLE 1

| Step | | Desig- | | | Duration |
|---|---|---|---|---|---|
| # | Side | nation | Medium | Concentration | [s] |
| 0 | Facing side | DIW | DIW | | 3-8 |
| 1 | Facing side | O3W | O₃ + DIW | 15-20 ppm | 25 |
| 2 | Facing side | DIW | DIW | | 10 |
| 3 | Facing side | SC1 | TMAH + | TMAH 0.3%, | 20 |
| | | | H₂O₂ + | H₂O₂ 0.7% | |
| | | | DIW | | |
| 4 | Facing side | DIW | DIW | | 20 |
| 5 | Facing side/ | O3W | O₃ + DIW | 15-20 ppm | 20 |
| | Reverse side | | | | |
| 6 | Facing side/ | HF | HF + DIW | 0.5-1% | 3 |
| | Reverse side | | | | |
| 7 | Facing side/ | O3W | O₃ + DIW | 15-20 ppm | 20 |
| | Reverse side | | | | |
| 8 | Facing side/ | HF | HF + DIW | 0.5-1% | 3 |
| | Reverse side | | | | |
| 9 | Facing side/ | O3W | O₃ + DIW | 15-20 ppm | 20 |
| | Reverse side | | | | |
| 10 | Facing side/ | HF | HF + DIW | 0.5-1% | 3 |
| | Reverse side | | | | |
| 11 | Facing side/ | O3W | O₃ + DIW | 15-20 ppm | 20 |
| | Reverse side | | | | |
| 12 | Facing side/ | DIW | DIW | | 10 |
| | Reverse side | | | | |
| 13 | Facing side/ | DRY | N₂ | | 26 |
| | Reverse side | | | | |

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

1. A method for cleaning a facing side and a reverse side of a semiconductor wafer, the method comprising, in the order given:
cleaning the facing side of the semiconductor wafer, the cleaning of the facing side comprising, in the order given:
a precleaning step with water, the precleaning step executed such that the facing side is still wet as the next cleaning step begins;
a first cleaning step comprising cleaning with ozonized water and a subsequent rinsing step with purified water;
a second cleaning step, which comprises a treatment step with ozonized water followed by a treatment step with a liquid containing hydrogen fluoride (HF); and
a third cleaning step comprising cleaning with ozonized water and a subsequent rinsing step with purified water; and
jointly cleaning the facing side and the reverse side of the semiconductor wafer, the jointly cleaning the facing side and the reverse side comprising: a fourth cleaning step, which comprises a treatment step with ozonized water followed by a treatment step with a liquid comprising HF, and a drying step, in which both the facing side and the reverse side of the semiconductor wafer are dried.

2. The method as claimed in claim 1, wherein the second cleaning step is repeated multiply.

3. The method as claimed in claim 1, wherein the third cleaning step is followed by a drying step in which the facing side of the semiconductor wafer is dried.

4. The method as claimed in claim 1, wherein the fourth cleaning step is repeated multiply.

5. The method as claimed in claim 1, wherein the fourth cleaning step is repeated more than three times.
